(19) United States
(12) Patent Application Publication
(10) Pub. No.: US 2025/0380488 A1
(43) Pub. Date: Dec. 11, 2025

(54) STACKED FETS WITH LATERAL GATE CONTACT PLUGS

(71) Applicant: INTERNATIONAL BUSINESS MACHINES CORPORATION, Armonk, NY (US)

(72) Inventors: Shay Reboh, Guilderland, NY (US); Chen Zhang, Santa Clara, CA (US); Ruilong Xie, Niskayuna, NY (US); Shahrukh Khan, Sandy Hook, CT (US)

(21) Appl. No.: 18/739,723

(22) Filed: Jun. 11, 2024

(51) Int. Cl. H01L 29/423; H01L 21/822; H01L 21/8238; H01L 27/06; H01L 27/092; H01L 29/06; H01L 29/66; H01L 29/775; H01L 29/786

(52) U.S. Cl. CPC H10D 84/038; H10D 30/014; H10D 30/43; H10D 30/6735; H10D 30/6757; H10D 62/121; H10D 84/0186; H10D 84/0188; H10D 84/856; H10D 88/00; H10D 88/01

(57) ABSTRACT

A semiconductor device includes a merged gate having a top gate and a bottom gate disposed within a gate column with the top gate. A lateral contact plug is disposed between the top gate and the bottom gate to connect the top gate and the bottom gate, the lateral contact plug being confined within a width of the top gate.

### BACKGROUND

The present invention relates generally to semiconductor devices and methods for fabrication, and more particularly to stacked field effect transistor devices (FETs) having gate contact plugs to join stacked gate conductors.

Semiconductor devices are used in a variety of electronic applications, such as personal computers, cell phones, digital cameras, and other electronic equipment. Semiconductor devices are usually fabricated by sequentially depositing insulating or dielectric layers, conductive layers, and semiconductive layers over a semiconductor substrate and patterning the various material layers using lithography to form circuit components and elements thereon.

The semiconductor industry has experienced rapid growth due to improvements in the integration density of a variety of electronic components (e.g., transistors, diodes, resistors, capacitors, etc.). For the most part, this improvement in integration density has come from shrinking the semiconductor process node. With the increased demands for miniaturization, higher speed, greater bandwidth, lower power consumption, and lower latency, chip layout has become more complicated and difficult to achieve in the production of semiconductor dies.

Stacked transistor devices may be used to increase areal density of devices on a chip. Additionally, the close proximity of the overlying and underlying devices can be useful when forming paired devices, such as complementary semiconductor devices that include two devices of opposing polarity. However, positioning transistors above one another places spatial and electrical constraints that can make it challenging to provide required performance.

In sequential stacked FETs integration (bonding flow), gates of top and bottom FETs are not initially interconnected as a bonding dielectric is disposed between them as part of the fabrication process. To make a connection between top and bottom gates a vertical via is needed to be formed on an outside surface of the gate structures prior to forming a top gate metal. This process adds process complexity and adds fabrication steps and time. In addition, the vertical via consumes critical device area.

Therefore, a need exists for stacked transistor devices that includes a connection between top and bottom gates in a stacked device structure after top and bottom gates have been formed that can reduce process complexity, increase reliability, reduce processing steps and time and reduce or maintain device area.

### SUMMARY

In accordance with an embodiment of the present invention, a semiconductor device includes a merged gate having a top gate and a bottom gate disposed within a gate column with the top gate. A lateral contact plug is disposed between the top gate and the bottom gate to connect the top gate and the bottom gate, the lateral contact plug being confined within a width of the top gate.

In other embodiments, the lateral contact plug can extend an entire width of the top gate or over a portion of the width of the top gate. The lateral contact plug can include a bonding dielectric disposed between portions of the lateral contact plug. A dielectric plug can separate a source/drain region of a top field effect transistor from a source/drain region of a bottom field effect transistor. The bonding dielectric can be selectively etchable relative to the dielectric plug. The lateral contact plug can include a different material than a conductor for the top gate.

In accordance with another embodiment of the present invention, a semiconductor device, includes a stacked transistor structure having field effect transistors on vertically stacked levels, the vertically stacked levels having a gate stack including a top gate and a bottom gate. A lateral contact plug is disposed between the top gate and the bottom gate to connect the top gate and the bottom gate, the lateral contact plug being confined within a width of the top gate.

In other embodiments, the lateral contact plug can extend an entire width of the top gate or over a portion of the width of the top gate. The lateral contact plug can include a bonding dielectric disposed between portions of the lateral contact plug. The field effect transistors can include source/drain regions on the vertically stacked levels such that a source/drain region of a top field effect transistor is disposed over a source/drain region of a bottom field effect transistor. The source/drain region of the top field effect transistor can be separated from the source/drain region of the bottom field effect transistor by a dielectric plug. The lateral contact plug can include a different material than a conductor for the top gate.

In accordance with another embodiment of the present invention, a method for fabricating a semiconductor device includes forming a bottom gate structure; forming a dielectric layer on the bottom gate structure; forming a top gate structure on the dielectric layer; etching gate cut trenches through the top gate structure, the dielectric layer and the top gate structure to form a gate column, the gate column including a top gate and a bottom gate; etching the dielectric layer through the gate cut trenches to form recesses in the dielectric layer from sidewalls of the gate column; and filling the recesses with a conductive material to form a lateral contact plug to connect the top gate and the bottom gate within the sidewalls of the gate column.

In other embodiments, etching the dielectric layer can include removing the dielectric layer from in between the top gate and the bottom gate. Filling the recesses can include forming the lateral contact plug to extend an entire width of the gate column. Filling the recesses can include forming the lateral contact plug to extend a portion of a width of the gate column. Filling the recesses with the conductive material can include depositing a metal over surfaces of the top gate and the bottom gate, the metal being selectively removable relative to the surfaces. The top gate can be associated with a source/drain region of a top field effect transistor and the bottom gate can be associated with a source/drain region of a bottom field effect transistor, the method can further include forming a dielectric plug separating the source/drain region of the top field effect transistor from the source/drain region of the bottom field effect transistor.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a layout view with section lines labeled X and Y where cross-sections are taken of a semiconductor device depicted in cross-sectional views of FIGS. 1-16 and showing a cross-sectional view after a bottom field effect transistor is fabricated, in accordance with an embodiment of the present invention;

FIG. 2 shows a cross-sectional view after a dielectric layer is formed over the semiconductor device, in accordance with an embodiment of the present invention;

FIG. 3 shows a cross-sectional view after bonding a nanosheet on the dielectric layer, in accordance with an embodiment of the present invention;

FIG. 4 shows a cross-sectional view after forming a top dummy gate and recessing the nanosheet and the dielectric layer, in accordance with an embodiment of the present invention;

FIG. 5 shows a cross-sectional view after replacing the dielectric layer with a dielectric plug having a different etch selectivity than the bonding dielectric, in accordance with an embodiment of the present invention;

FIG. 6 shows a cross-sectional view after forming top source/drain regions over the dielectric plug, in accordance with an embodiment of the present invention;

FIG. 7 shows a cross-sectional view after forming an interlayer dielectric, in accordance with an embodiment of the present invention;

FIG. 8 shows a cross-sectional view after a replacement metal gate process to form a top gate structure, in accordance with an embodiment of the present invention;

FIG. 9 shows cross-sectional views after gate cut trenches are formed, in accordance with an embodiment of the present invention;

FIG. 10 shows cross-sectional views after the dielectric layer is partially recessed by etching through the gate cut trenches, in accordance with an embodiment of the present invention;

FIG. 11 shows cross-sectional views forming a metal liner over top and bottom gates and within recesses between the gates, in accordance with an embodiment of the present invention;

FIG. 12 shows cross-sectional views after selectively removing the metal liner from sidewalls of the gates but not from within the recesses between the gates, in accordance with an embodiment of the present invention;

FIG. 13 shows cross-sectional views after forming a gate cut, in accordance with an embodiment of the present invention;

FIG. 14 shows cross-sectional views after the dielectric layer is fully recessed by etching through the gate cut trenches, in accordance with an embodiment of the present invention;

FIG. 15 shows cross-sectional views forming a metal liner over top and bottom gates and within full recesses between the gates, in accordance with an embodiment of the present invention; and

FIG. 16 shows cross-sectional views after selectively removing the metal liner from sidewalls of the gates but not from within the recesses between the gates and after forming a gate cut, in accordance with an embodiment of the present invention.

### DETAILED DESCRIPTION

In accordance with embodiments of the present invention, devices and methods are described which include stacked field effect transistor (FET) devices having interdevice connections between gates in a stacked device column. In stacked FET devices, methods and devices can employ an inter-gate connection or merged gate in, e.g., 60% or more of devices on a chip. In an embodiment, after the formation of a bottom gate and a top gate in a stacked device structure, a gate cut process is performed to divide the top and bottom gates along their length. Once the gate cut is opened, a dielectric layer is completely removed between the bottom gate and the top gate. The dielectric layer can include a bonding dielectric in the case of bonded wafers or sequential integration. A conductive material is deposited to completely fill in between the bottom gate and the top gate to form a lateral contact plug or via to form a merged gate.

In another embodiment, after the formation of a bottom gate and a top gate in a stacked device structure, a gate cut process is performed to divide the top and bottom gates along their length. Once the gate cut is opened, a dielectric layer is recessed between the bottom gate and the top gate from end portions of a gate column. A conductive material is deposited in the recessed portions to form lateral contacts plugs or vias. The lateral contact plugs extend below transistor channels and provide improved contact area. The lateral contact plugs in between the bottom gate and the top gate form a merged gate.

In accordance with embodiments of the present invention, stacked FETs having a lateral contact plug that connects top and bottom gates at an edge of the gates in between stacked gate structures provides a low area profile while still providing a merged gate. The lateral contact plugs can extend under the transistor channels to occupy less space while providing a less resistive contact. The lateral contact via can extend across all or part of the gate width. The lateral contact plug can include a same or different conductive material than conductive material employed for the top or bottom gates.

In accordance with embodiments of the present invention, methods for fabricating a semiconductor device includes forming stacked FETs, e.g., forksheet FETs, nanosheet FETs, or any other stacked FET structure. The stacked FETs include gate structures and source/drain regions. The gate structures include a top gate and a bottom gate stacked on top of each other. A gate cut is performed to divide a longitudinal length of the gate structures to define individual gate columns. Each gate column has a top gate and a bottom gate. The top gate and the bottom gate are separated by a dielectric layer, e.g., a bonding dielectric, such as a bonding oxide.

The gate cut exposes lateral sides of the gate columns and permits access to the dielectric layer. The dielectric layer is exposed to an etchant to laterally recess or completely remove the dielectric layer from between the top gate and the bottom gate. The recess or space is filled with a conductive material followed by an etch process to remove excess material outside of the space between the top gate and the bottom gate (e.g., removed from the gate cut and sidewalls of the top gate and the bottom gate). The conductive material that remains in the space between the top gate and the bottom gate form the lateral contact plug.

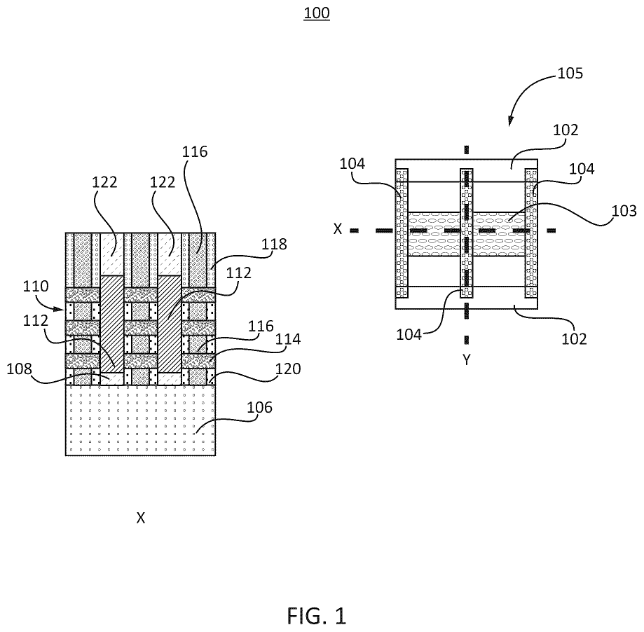

Referring now to the drawings in which like numerals represent the same or similar elements and initially to FIG. 1, devices and methods for manufacturing a stacked field effect transistor (FET) device are shown in accordance with embodiments of the present invention. A layout view 105 of a wafer 100 is shown. The layout view 105 shows active region lines 102 and gate lines 104. A gate cut 103 is also shown. Section lines X and Y are indicated and show cross-sectional cuts for corresponding sections labeled “X” and “Y” throughout FIGS. 1-16. Active region lines 102 represent stacked source/drain (S/D) regions for transistor devices, and gate lines 104 represent gate structures for such transistor devices. Transistor channels are formed along the active region lines 102 below the gate lines 104. Section line X cuts across the gate lines 104 and section line Y cuts along the gate line 104.

The wafer 100 includes a substrate 106, which can have a single layer or multiple layers on which a stacked FET device will be fabricated. The substrate 106 can include any suitable substrate structure, e.g., a bulk semiconductor, a semiconductor-on-insulator (SOI) substrate, etc., and preferably includes a monocrystalline semiconductor. In one example, the substrate 106 can include a silicon-containing material. Illustrative examples of Si-containing materials suitable for the substrate 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc. The substrate 106 can include shallow trench isolation (STI) regions and other structures in accordance with a semiconductor device being fabricated.

A bottom FET 110 is fabricated on the substrate 106. The bottom FET 110 includes source/drain regions 112 formed on a dielectric material 108 to isolate the source/drain regions 112 from the substrate 106. The bottom FET 110 can be fabricated using a layer stack or stacks applied to or formed on the substrate 106. In an embodiment, one or more nanosheets (NS) can be applied to the substrate 106. The layer stack of the nanosheet is processed to form channel layers 114 for the bottom FET 110 from alternating layers of the nanosheet. The other layers of the nanosheet are removed but are employed for forming inner spacers 120. The inner spacers 120 and spacers 118 include a dielectric material, e.g., a nitride or an oxide. The inner spacers 120 can be formed by laterally etching the nanosheet layer and then filling the recess with a dielectric material. Remaining portions of the nanosheet layer that were recessed for the inner spacers 120 are removed to expose the channel layers 114.

The source/drain regions 112 can be grown using an epitaxial growth process using the channel layer 114 to initiate crystal growth. The source/drain regions 112 can include Si or SiGe. In one embodiment, the source/drain regions 112 can be designated as P-type or N-type devices. For example, if the source/drain regions 112 include N-type devices then the source/drain regions 112 can include Si. In another example, if the source/drain regions 112 include P-type devices then the source/drain regions 112 can include SiGe. The source/drain regions 112 can be appropriately doped during their formation. For example, the source/drain regions 112 can be doped by introducing p dopants (e.g., B, Ga, etc.) during epitaxial formation. Similarly, the source/drain regions 112 can be doped by introducing n dopants (e.g., P, As, etc.) during epitaxial formation. In other embodiments, P-type and N-type devices can be formed adjacent to one another. Processing would include forming one device type and then the other device type by employing block masks to protect each device during processing of the other.

In some embodiments, a dummy gate material is first employed for dummy gates (not shown). The dummy gates are removed and a gate dielectric layer (not shown) is deposited to cover the channel layers 114. The gate dielectric layer can be formed by, e.g., chemical wet processes, chemical vapor deposition (CVD) and/or atomic layer deposition (ALD). Suitable examples of the gate dielectric layer can include a silicon oxide interface layer followed by a high-K dielectric oxide that can include, but is not limited to: Al₂O₃, ZrO₂, HfO₂, Ta₂O₃, TiO₂ and combinations thereof.

The bottom gate 116 is formed over the gate dielectric layer and fills spaces between the channel layers 114 that the dummy gates once occupied. This process is known as a replacement metal gate (RMG) process to form High-K Metal Gate (HKMG) structures for selectively activating FETs. The bottom gate 116 can include at least one gate conductor. The gate conductor can include any conductive metal including, but not limited to W, Ni, Ti, Mo, Ta, Cu, Pt, Ag, Au, Ru, Ir, Rh, and Re, and alloys that include at least one of these conductive materials. The gate conductor can include one or more layers of conductive materials. In one example, a second conductive material may be formed. When a combination of conductive elements is employed, an optional diffusion barrier material such as TaN or WN may be formed between the conductive materials. The gate conductor can be deposited by CVD, plasma enhanced CVD (PECVD), ALD or other suitable deposition process.

Dielectric cap 122 is deposited over the wafer 100. The dielectric cap 22 can include any suitable material, e.g., silicon containing materials such as SiO₂, Si₃N₄, SiOₓN_{y}, SiC, SiCO, SiCOH, and SiCH compounds. The dielectric cap 122 can be deposited using CVD, although other deposition methods can be employed. The dielectric cap 122 is planarized, e.g., by chemical mechanical polishing (CMP).

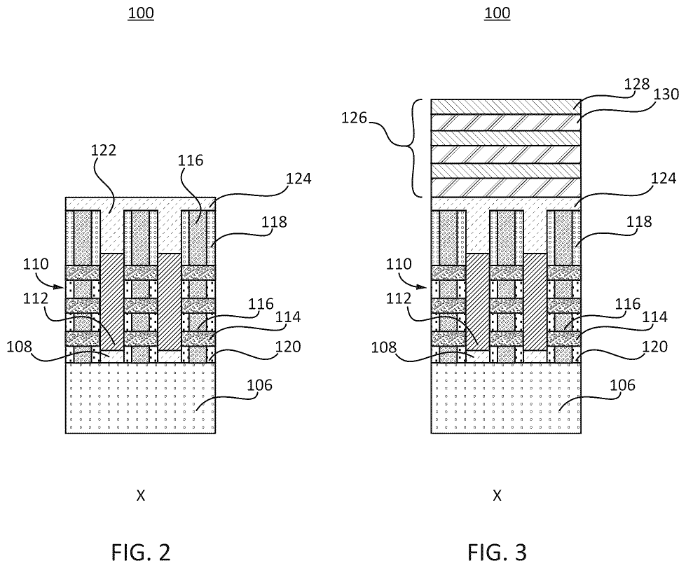

Referring to FIG. 2, a dielectric layer 124 is deposited over the wafer 100. The dielectric layer 124 can include an oxide, although other dielectric materials can be employed. The dielectric layer 124 can be deposited using CVD, ALD or any other suitable deposition methods. The dielectric layer 124 can include a bonding dielectric. The dielectric layer 124 provides a barrier between the bottom gate 116 and a top gate to be formed. The dielectric layer 124 provides separation from the bottom FET 110 to enable continued processing for the formation of a top FET.

Referring to FIG. 3, a nanosheet 126 is applied to the dielectric layers 124 to adhere the nanosheets to the wafer 100. The nanosheet 126 includes alternating layers 128, 130 of semiconductor materials. The alternating layers 128, 130 can include, e.g., Si and SiGe. The nanosheet 126 will be employed in the formation of a top FET. The top FET will be processed in a similar way as the bottom FET 110.

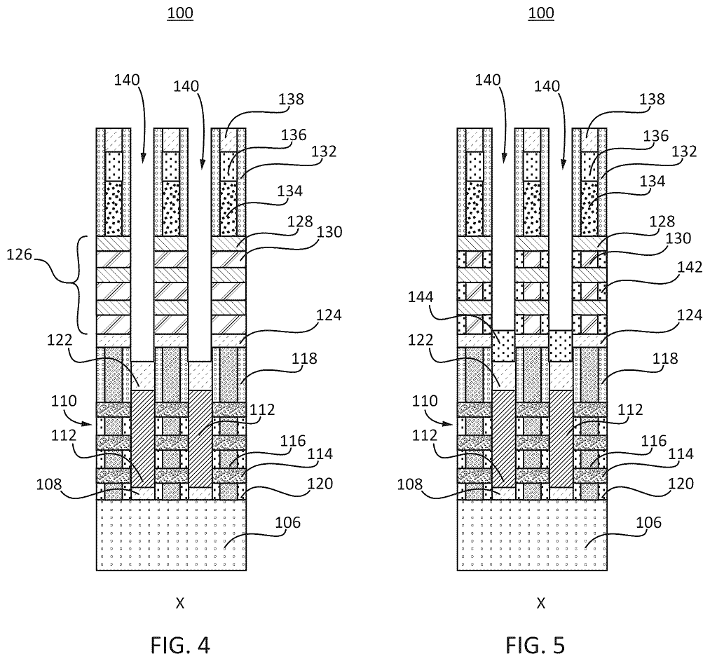

Referring to FIG. 4, the nanosheet 126 is patterned using dummy gate structures. A dummy gate material 134 for dummy gates is blanketed over the wafer 100 to cover the nanosheet 126 followed by a blanket deposition of a hard mask material to later form a patterned hard mask 136, e.g., by using photolithographic patterning. The dummy gate material 134 can include a polysilicon, amorphous Si or other selectively removeable material. The hard mask material is patterned to form hard mask 136. The patterned hard mask 136 is employed to etch the dummy gate material 134. Then, a deposition process is employed to form spacers 132. Spacers 132 can include an oxide, such as silicon dioxide, although other dielectric materials can be employed.

The patterned hard mask 136 and spacers 132 can be employed as an etch mask to recess the nanosheet 126 to form trenches 140. Regions of the nanosheet 126 below the hard mask 136 and spacers 132 are patterned for further processing while the nanosheet 126 is completely removed in other regions. The dielectric layer 124 is also recessed using an anisotropic etch, such a, e.g., a reactive ion etch (RIE). A dielectric cap 138 can be formed over the patterned hard mask 136.

Referring to FIG. 5, a dielectric material is deposited over the wafer 100 and recessed into the trenches 140 as a dielectric layer replacement material. The dielectric is recessed using, e.g. CMP to form a dielectric plug 144 disposed at a same level as the dielectric layer 124. The dielectric plug 144 can include a material that is selectively etchable relative to the dielectric layer 124. For example, if the dielectric layer 124 includes an oxide, the dielectric plug 144 can include a nitride.

Inner spacers 142 are also formed and include a dielectric material. In an embodiment, the inner spacers 142 are formed by recessing exposed portions of a semiconductor layer of the alternating layers 130. A dielectric material is deposited to fill in the recessed portions to form the inner spacers 142.

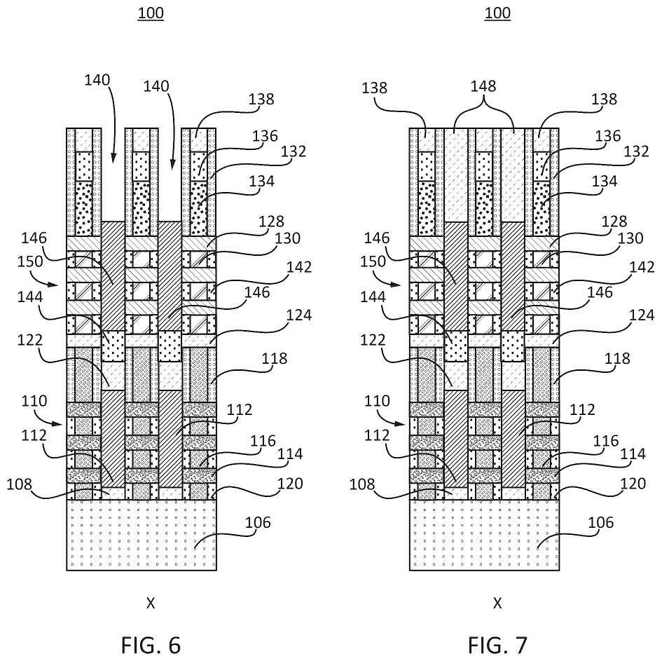

Referring to FIG. 6, source/drain regions 146 are formed in trenches 140 by an epitaxial growth process. The source/drain regions 146 can be grown using the alternating layers 128 to initiate crystal growth. The alternating layers 128 form channel layers for a top FET 150. The source/drain regions 146 can include Si or SiGe. In one embodiment, the source/drain regions 146 can be designated as P-type or N-type devices. For example, if the source/drain regions 146 include N-type devices then the source/drain regions 146 can include Si. In another example, if the source/drain regions 146 include P-type devices then the source/drain regions 146 can include SiGe. The source/drain regions 146 can be appropriately doped during their formation. For example, the source/drain regions 146 can be doped by introducing p dopants (e.g., B, Ga, etc.) during epitaxial formation. Similarly, the source/drain regions 146 can be doped by introducing n dopants (e.g., P, As, etc.) during epitaxial formation. In other embodiments, P-type and N-type devices can be formed adjacent to one another. Processing would include forming one device type and then the other device type by employing block masks to protect each device during processing of the other.

Referring to FIG. 7, an interlayer dielectric (ILD) 148 is deposited over the wafer 100. The interlayer dielectric 148 can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The interlayer dielectric 148 can be deposited using CVD, although other deposition methods can be employed. The interlayer dielectric 148 is planarized, e.g., by CMP.

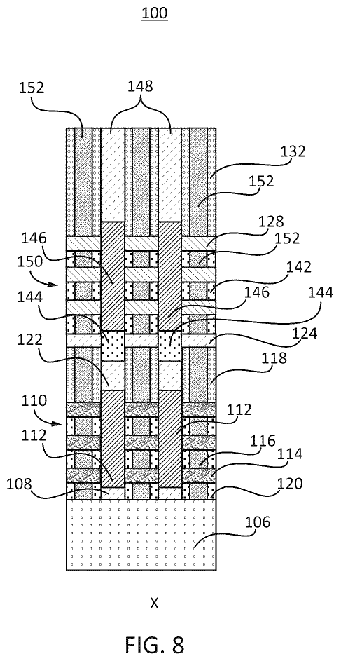

Referring to FIG. 8, the dielectric cap 138, the hard mask 136 and the dummy gate material 134 are removed. A gate dielectric layer (not shown) is deposited to cover the channel layers of the alternating layers 128. The gate dielectric layer can be formed by, e.g., chemical wet processes, CVD and/or ALD. Suitable examples of the gate dielectric layer can include a silicon oxide interface layer followed by a high-K dielectric oxide that can include, but is not limited to: Al₂O₃, ZrO₂, HfO₂, Ta₂O₃, TiO₂ and combinations thereof.

A top gate 152 is formed over the gate dielectric layer and fills spaces between the channel layers of the alternating layers 128 that the dummy gate material 134 once occupied. This process is known as a RMG process to form HKMG structures for selectively activating FETs. The top gate 152 can include at least one gate conductor. The gate conductor can include any conductive metal including, but not limited to W, Ni, Ti, Mo, Ta, Cu, Pt, Ag, Au, Ru, Ir, Rh, and Re, and alloys that include at least one of these conductive materials. The gate conductor can include one or more layers of conductive materials. In one example, a second conductive material may be formed. When a combination of conductive elements is employed, an optional diffusion barrier material such as TaN or WN may be formed between the conductive materials. The gate conductor can be deposited by CVD, plasma enhanced CVD (PECVD), ALD or other suitable deposition process.

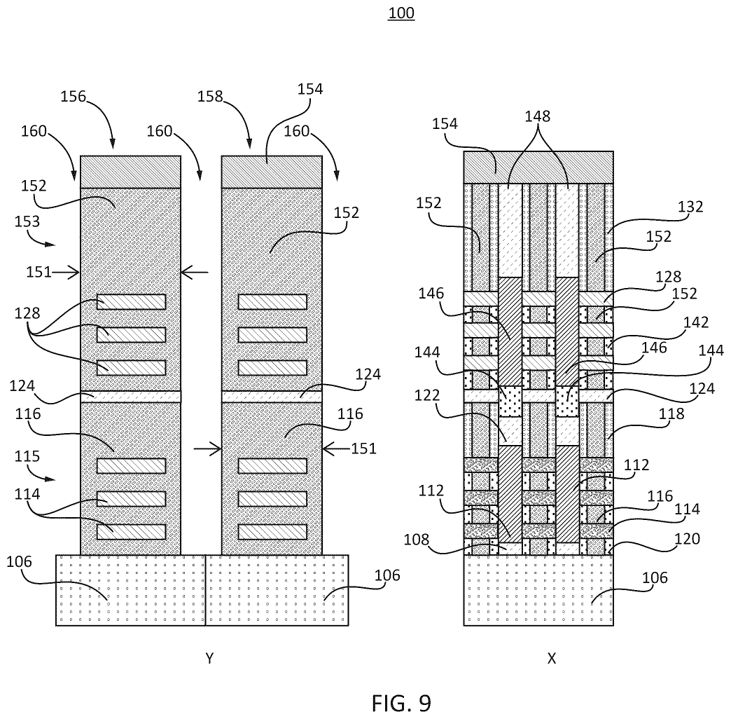

Referring to FIG. 9, a gate cut process is performed in accordance with embodiments of the present invention. A gate cut process includes dividing a gate line (e.g., a high-k metal gate or HKMG). The gate line includes a bottom gate structure 115 and a top gate structure 153, which are separated by the dielectric layer 124. The metal of the gate conductor is cut (e.g., by an etching process) to separate the gate conductor into two or more portions that form gate stacks 156, 158 or gate columns. Each gate column or gate stack 156 or 158 includes the top gate 152 and the bottom gate 116. The dielectric layer 124 is disposed between the top gate 152 and the bottom gate 116 of cach gate stack 156 or 158.

The gate cut process includes forming an etch mask 154 on the gate conductor or the top gate 152 and patterning the etch mask 154 using, e.g., a lithographie patterning process. The lithographic patterning process can include use of a photoresist (not shown) over material deposited of the etch mask 154 by photoresist coating, exposing, post-exposure baking, and developing. The patterned photoresist provides openings that are transferred by etching into the etch mask 154. The patterned photoresist is then removed. The etch mask 154 can include titanium nitride, silicon nitride, amorphous silicon, yttrium silicate (YSiOₓ), or other suitable etch mask material(s). The gate conductor is etched, e.g., using a RIE, in accordance with the etch mask 154 to form trenches 160 or gate cut openings down to the substrate 106. Within the trenches 160, end portions of the dielectric layer 124 are exposed. The dielectric layer 124 extends over a width 151 of the gate column or gate stack 156, 158.

It should be understood that the gate cut process could also have been conducted earlier on in the process on the dummy gate structures. In such a case, the gate cut could be done at the dummy gate level (gate cut first) and filled with a sacrificial dielectric and at this point in the process, the sacrificial dielectric would be removed to open the gate cut cavity.

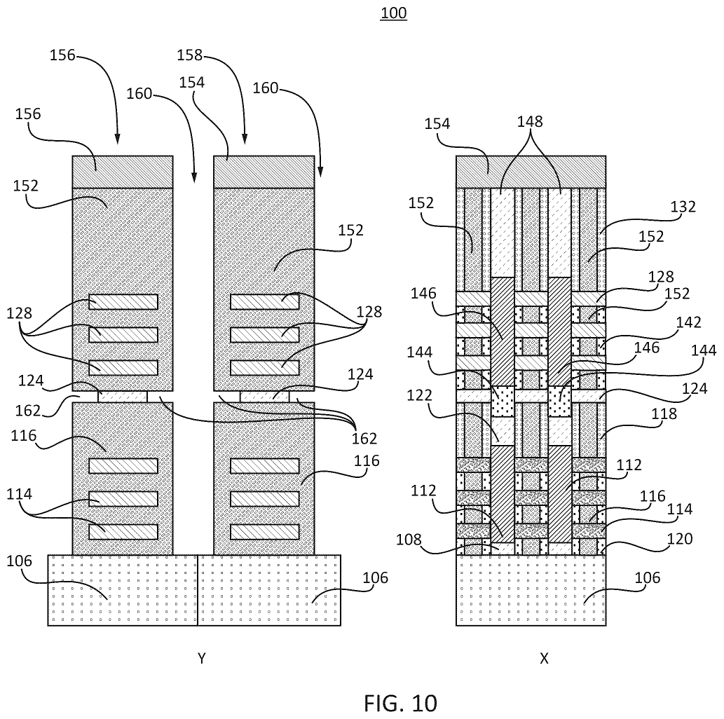

Referring to FIG. 10, an etch process is performed to laterally recess the dielectric layer 124. The etch process can include wet etching, dry etching or other suitable etching methods. The etch process selectively removes the dielectric layer 124 relative to the material of the gate conductor of the top gate 152 and the bottom gate 116 as well as the substrate 106. The etch process selectively removes the dielectric layer 124 relative to the dielectric plug 144, which had its material selected so as to not be etched when recessing the dielectric layer 124.

In an embodiment, the etch process does not remove all of the dielectric layer 124 and instead forms recesses 162 in the dielectric layer 124. The etch process can be tuned to selectively etch the dielectric layer 124 without etching the gate conductors of the top gate 152 and the bottom gate 116. For example, a dry etching process using hydrogen fluoride (HF) and ammonia can be employed, and may use argon gas as a carrier.

In the case of a gate-cut first, after the sacrificial dielectric is removed, the high-K dielectric is removed in the gate cut.

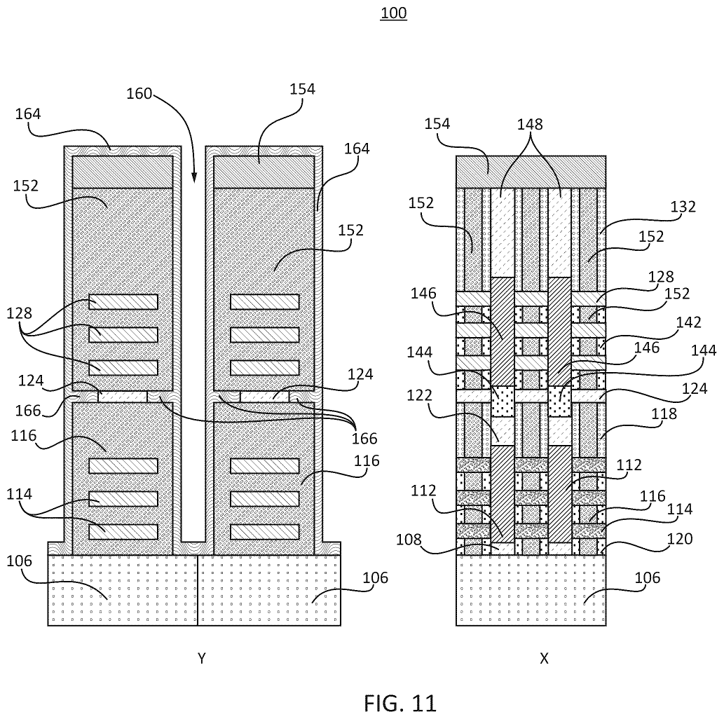

Referring to FIG. 11, a metal liner 164 is conformally deposited over the gate conductor of the top gate 152 and the bottom gate 116. The metal liner 164 fills in the recesses 162 (FIG. 10) up to the dielectric layer 124 and contacts surfaces between the top gate 152 and the bottom gate 116. The metal liner 164 can include any suitable conductive material that can be removed from the surfaces of the gate conductor of the top gate 152 and/or the bottom gate 116 without removing the metal liner 164 that fills the recesses 162. The metal liner 164 includes a material that is different than the material of the gate conductor of the top gate 152. For example, in an embodiment, if the gate conductor of the top gate 152 and/or the bottom gate 116 includes W or compounds containing W then the metal liner 164 can include Co or compounds containing Co. The metal liner 164 can be deposited using a CVD, PECVD, ALD or any other suitable deposition process.

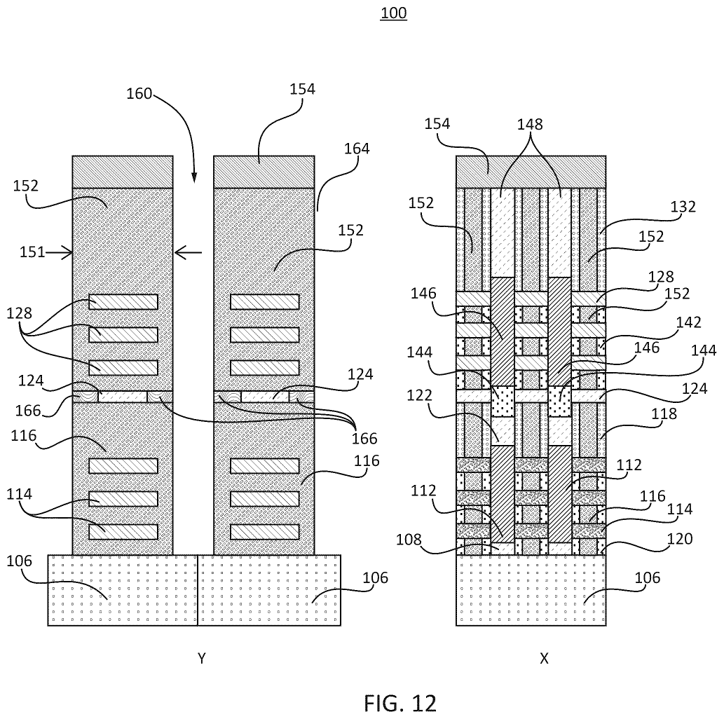

Referring to FIG. 12, the metal liner 164 is removed from over the gate conductor of the top gate 152 and the bottom gate 116. The metal liner 164 remains within the recesses 162 (FIG. 10) up to the dielectric layer 124 and forms lateral contact plugs 166 within the sidewalls of the top gate 152 and/or the bottom gate 116. The lateral contact plugs 166 contact surfaces between the top gate 152 and the bottom gate 116. The lateral contact plugs 166 occupy a portion of the width 151 not occupied by the dielectric layer 124. The lateral contact plugs 166 make an electrical connection between the top gate 152 and the bottom gate 116 for each gate stack 156 and 158. The lateral contact plugs 166 provide merged gates having a low profile in that the lateral contact plugs 166 are disposed between the top gate 152 and the bottom gate 116 and therefore do not consume device real estate as the lateral contact plugs 166 are confined within the width 151 of the top gate 152.

The metal liner 164 can be removed using a wet etch or a dry etch process. The metal liner 164 is removed from the surfaces of the gate conductor of the top gate 152 and the bottom gate 116 without removing the metal liner 164 that fills the recesses 162. In the example, if the gate conductor of the top gate 152 and the bottom gate 116 includes W then the metal liner 164 can include Co. Portions of the metal liner 164 can selectively remove, e.g., Co relative to W (of the gate conductor of the top gate 152 and the bottom gate 116) by a wet etch.

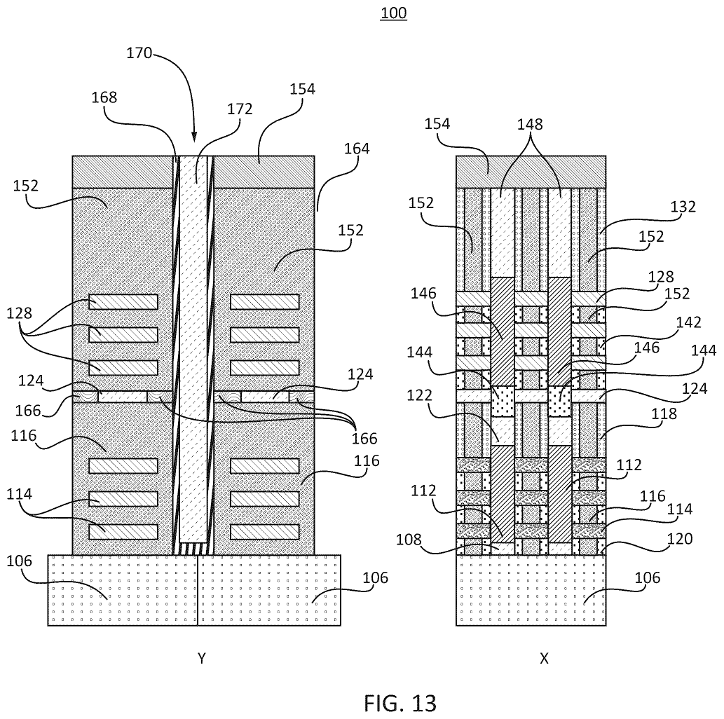

Referring to FIG. 13, the trenches 160 (FIG. 12) are filled to provide a gate cut 170. The trenches 160 can be filled with one or more dielectric materials followed by a planarization process, e.g., CMP to planarize a free surface of the wafer 100.

In an embodiment, the one or more dielectric materials of the gate cut 170 can include a liner layer 168 and inner dielectric 172. The liner layer 168 and the inner dielectric 172 can include different materials and can be selected from any suitable dielectric material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The liner layer 168 and the inner dielectric 172 can be deposited using CVD, although other deposition methods can be employed.

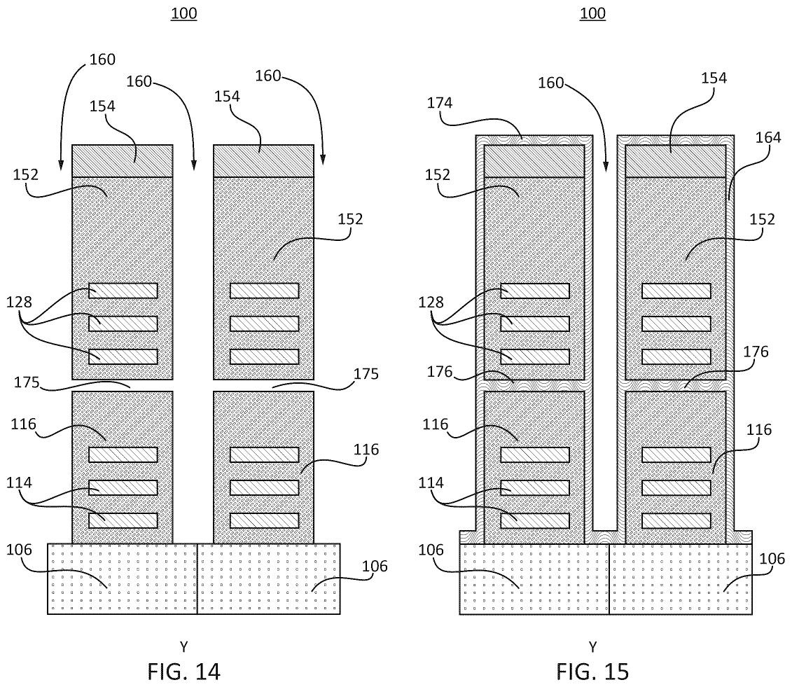

Referring to FIG. 14, in another embodiment, an etch process is performed to laterally recess the dielectric layer 124. The etch process can include wet etching, dry etching or other suitable etching methods. The etch process selectively removes the dielectric layer 124 relative to the material of the gate conductor of the top gate 152 and the bottom gate 116 as well as the substrate 106. The etch process also selectively removes the dielectric layer 124 relative to the dielectric plug 144 (FIG. 10), which had its material selected so as to not be etched when recessing the dielectric layer 124. In this embodiment, the etch process removes all of the dielectric layer 124 in between the top gate 152 and the bottom gate 116 by completely laterally recessing the dielectric layer 124 to form spaces 175. The etch process can be tuned to selectively etch the dielectric layer 124 without etching the gate conductors of the top gate 152 and the bottom gate 116. For example, a dry etching process using hydrogen fluoride (HF) and ammonia can be employed, and may use argon gas as a carrier.

Referring to FIG. 15, a metal liner 174 is conformally deposited over the gate conductor of the top gate 152 and the bottom gate 116. The metal liner 174 fills in spaces 175 between the top gate 152 and the bottom gate 116 in between the sidewalls of the top gate 152 and/or the bottom, gate 116. The metal liner 174 can include any suitable conductive material that can be removed from the surfaces of the gate conductor of the top gate 152 and/or the bottom gate 116 without removing the metal liner 174 that fills the spaces 175. The metal liner 174 includes a material that is different than the material of the gate conductor of the top gate 152. For example, in an embodiment, if the gate conductor of the top gate 152 or the bottom gate 116 includes W or compounds containing W than the metal liner 174 can include Co or compounds containing Co. The metal liner 174 can be deposited using a CVD, PECVD or any other suitable deposition process.

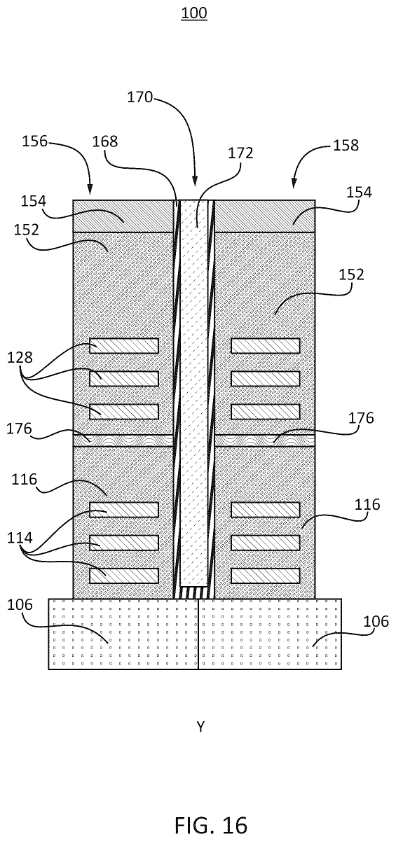

Referring to FIG. 16, the metal liner 174 is removed from over the gate conductor of the top gate 152 and the bottom gate 116. The metal liner 174 remains within the spaces 175 (FIG. 14) and forms lateral contact plugs 176 within the sidewalls of the top gate 152 and/or the bottom gate 116. The lateral contact plugs 176 contact surfaces between the top gate 152 and the bottom gate 116. The lateral contact plugs 176 make an electrical connection between the top gate 152 and the bottom gate 116 for each gate stack 156 and 158. The lateral contact plugs 176 provide merged gates having a low profile in that the lateral contact plugs 176 are disposed between the top gate 152 and the bottom gate 116 and therefore do not consume device real estate as the lateral contact plugs 176 are confined within a width 151 (FIG. 12) of the top gate 152.

The metal liner 174 can be removed using a wet etch or a dry etch process. The metal liner 174 is removed from the surfaces of the gate conductor of the top gate 152 and the bottom gate 116 without removing the metal liner 174 that fills the spaces 175. In the example, if the gate conductor of the top gate 152 and the bottom gate 116 includes W then the metal liner 174 can include Co. Portions of the metal liner 174 can selectively remove, e.g., Co relative to W (of the gate conductor of the top gate 152 and the bottom gate 116) by a wet etch.

The trenches 160 (FIG. 14) are filled to provide the gate cut 170. The trenches 160 can be filled with one or more dielectric materials followed by a planarization process, e.g., CMP to planarize a free surface of the wafer 100. In an embodiment, the one or more dielectric materials of the gate cut 170 can include the liner layer 168 and the inner dielectric 172.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor-or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above.” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a merged gate including:
a top gate;
a bottom gate disposed within a gate column with the top gate; and
a lateral contact plug disposed between the top gate and the bottom gate to connect the top gate and the bottom gate, the lateral contact plug being confined within a width of the top gate.

2. The semiconductor device as recited in claim 1, wherein the lateral contact plug extends an entire width of the top gate.

3. The semiconductor device as recited in claim 1, wherein the lateral contact plug extends over a portion of the width of the top gate.

4. The semiconductor device as recited in claim 1, wherein the lateral contact plug includes a bonding dielectric disposed between portions of the lateral contact plug.

5. The semiconductor device as recited in claim 4, further comprising a dielectric plug separating a source/drain region of a top field effect transistor from a source/drain region of a bottom field effect transistor.

6. The semiconductor device as recited in claim 5, wherein the bonding dielectric is selectively etchable relative to the dielectric plug.

7. The semiconductor device as recited in claim 1, wherein the lateral contact plug includes a different material than a conductor for the top gate.

8. A semiconductor device, comprising:
a stacked transistor structure having field effect transistors on vertically stacked levels, the vertically stacked levels having a gate stack including a top gate and a bottom gate; and
a lateral contact plug disposed between the top gate and the bottom gate to connect the top gate and the bottom gate, the lateral contact plug being confined within a width of the top gate.

9. The semiconductor device as recited in claim 8, wherein the lateral contact plug extends an entire width of the top gate.

10. The semiconductor device as recited in claim 8, wherein the lateral contact plug extends over a portion of the width of the top gate.

11. The semiconductor device as recited in claim 8, wherein the lateral contact plug includes a bonding dielectric disposed between portions of the lateral contact plug.

12. The semiconductor device as recited in claim 8, wherein the field effect transistors include source/drain regions on the vertically stacked levels such that a source/drain region of a top field effect transistor is disposed over a source/drain region of a bottom field effect transistor.

13. The semiconductor device as recited in claim 12, wherein the source/drain region of the top field effect transistor is separated from the source/drain region of the bottom field effect transistor by a dielectric plug.

14. The semiconductor device as recited in claim 8, wherein the lateral contact plug includes a different material than a conductor for the top gate.

15. A method for fabricating a semiconductor device, comprising:
forming a bottom gate structure;
forming a dielectric layer on the bottom gate structure;
forming a top gate structure on the dielectric layer;
etching gate cut trenches through the top gate structure, the dielectric layer and the top gate structure to form a gate column, the gate column including a top gate and a bottom gate;
etching the dielectric layer through the gate cut trenches to form recesses in the dielectric layer from sidewalls of the gate column; and
filling the recesses with a conductive material to form a lateral contact plug to connect the top gate and the bottom gate within the sidewalls of the gate column.

16. The method as recited in claim 15, wherein etching the dielectric layer includes removing the dielectric layer from in between the top gate and the bottom gate.

17. The method as recited in claim 16, wherein filling the recesses includes forming the lateral contact plug to extend an entire width of the gate column.

18. The method as recited in claim 15, wherein filling the recesses includes forming the lateral contact plug to extend a portion of a width of the gate column.

19. The method as recited in claim 15, wherein filling the recesses with the conductive material includes depositing a metal over surfaces of the top gate and the bottom gate, the metal being selectively removable relative to the surfaces.

20. The method as recited in claim 15, wherein the top gate is associated with a source/drain region of a top field effect transistor and the bottom gate is associated with a source/drain region of a bottom field effect transistor and further comprising forming a dielectric plug separating the source/drain region of the top field effect transistor from the source/drain region of the bottom field effect transistor.
